(19) United States
(12) Patent Application Publication
(10) Pub. No.: US 2007/0235713 A1
(43) Pub. Date: Oct. 11, 2007

(54) SEMICONDUCTOR DEVICE HAVING CARBON NANOTUBE INTERCONNECTS AND METHOD OF FABRICATION

(75) Inventor: Thomas J. SWIRBEL, DAVIE, FL (US)

Correspondence Address: MOTOROLA, INC;INTELLECTUAL PROPERTY SECTION, LAW DEPT, 8000 WEST SUNRISE BLVD, FT LAUDERDAL, FL, 33322, US

(73) Assignee: MOTOROLA, INC., Plantation, FL (US)

(21) Appl. No.: 11/278,478

(22) Filed: Apr. 3, 2006

(51) Int. Cl. H01L 47/02; H01L 29/06

(52) U.S. Cl. 257/7

(57) ABSTRACT

An integrated circuit having carbon nanotube interconnects contains input/output pads situated on the upper surface, the pads arranged in an array having at least two rows. Carbon nanotubes are disposed on the input/output pads to provide electrical and thermal interconnection of the integrated circuit chip to another circuit such as a printed circuit board. The carbon nanotubes can be plated with one or more overlayers of metal.

### FIELD OF THE INVENTION

This invention relates generally to semiconductor devices. More particularly, this invention relates to semiconductor devices that have carbon nanotubes incorporated into the semiconductor device interconnect structure, and a method for forming the carbon nanotube interconnect structure.

### BACKGROUND

Electronic device miniaturization requires ever smaller semiconductor device packaging technologies. One such technology is a wafer level package. The wafer level package is a type of chip scale package which enables the integrated circuit (IC) die to be attached directly to a printed circuit board (PCB) face down, that is, with the IC's input/output (I/O) pads connecting to the PCB's pads through individual solder balls. This technology differs from other types of packages because there are no bond wires or interposer substrates. The principle advantage of the wafer level package is that the IC-to-PCB inductance is minimized. Secondary benefits are reduction in package size and manufacturing cycle time and enhanced thermal conduction characteristics, because today's faster semiconductor devices are operating at higher frequencies and thus generate significantly more heat. This traditional wafer level package and interconnect technology using solder bumped pads works well electrically and thermally down to 0.25 mm I/O pitch, but further miniaturization of pitch to accommodate very high I/O devices running at very high speeds may not be possible with this technology. The problem with the current art is the inability to have very fine pitch full array interconnects that have adequate aspect ratio (height-to-width) and conductivity for optimal performance.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is a perspective view of an integrated circuit having carbon nanotube interconnects in accordance with certain embodiments of the present invention.

FIG. 2 is a cross-sectional view of a portion of FIG. 1 in accordance with certain embodiments of the present invention. The relative size of some elements has been exaggerated for clarity.

FIG. 3 is a process flow chart depicting some of the steps of forming an integrated circuit having carbon nanotube interconnects in accordance with certain embodiments of the present invention.

### DETAILED DESCRIPTION

As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting; but rather, to provide an understandable description of the invention. The terms a or an, as used herein, are defined as one or more than one. The term plurality, as used herein, is defined as two or more than two. The term another, as used herein, is defined as at least a second or more. The terms including and/or having, as used herein, are defined as comprising (i.e., open language).

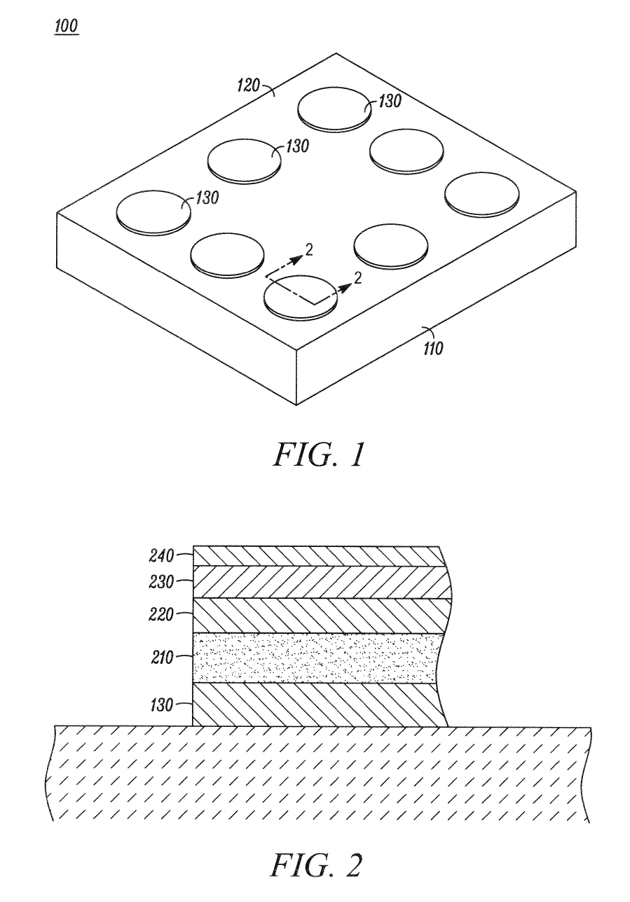

An integrated circuit having carbon nanotube interconnects contains a plurality of input/output pads disposed on an upper layer thereof, the pads arranged in an array having at least two rows. Carbon nanotubes are disposed on the input/output pads so as to provide electrical and thermal interconnection of the integrated circuit chip to another circuit such as a printed circuit board. The carbon nanotubes can optionally be plated with one or more overlayers of metal. Referring now to FIG. 1, a semiconductor device, such as an integrated circuit 100 typically consists of a silicon chip 110, cut from a silicon wafer, that has circuitry, such as transistors, interconnects, input and output pads or terminals 130, etc. on an upper surface 120. Traditionally, some of the circuitry is covered by a passivation layer to protect the sensitive transistors from environmental damage. The input/output (I/O) pads 130 are redistributed on a topmost layer in a full or partial array that is at least two rows wide, such that some, or all, of the pads are not covered by the passivation layer, but are exposed. Referring now to FIG. 2, a carbon nanotube or a clump of carbon nanotubes 210 is disposed on the individual input/output pads 130. Carbon nanotubes are molecular structures that can be either electrically conductive or semiconductive. In addition they have excellent thermal properties along an axis parallel to the tube wall. The measured thermal conductivity for a single tube is greater than 3000 W/meter-°K. In addition to the unique electrical and thermal properties of carbon nanotubes, they are capable of being fabricated with very high aspect ratios with geometries of 150 micron height and 30 micron diameter. The carbon nanotubes adhere to the I/O pads sufficient to provide mechanical connection, electrical connection, and thermal connection between the integrated circuit 100 and another circuit, such as a printed circuit board (not shown). Optionally, the carbon nanotubes 210 are plated with one or more metal layers 220, 230, 240 to provide additional environmental protection and to enhance solderability of the I/O pads. The metal layers 220, 230, 240 can be copper, nickel, gold, platinum, tin, lead, or alloys thereof.

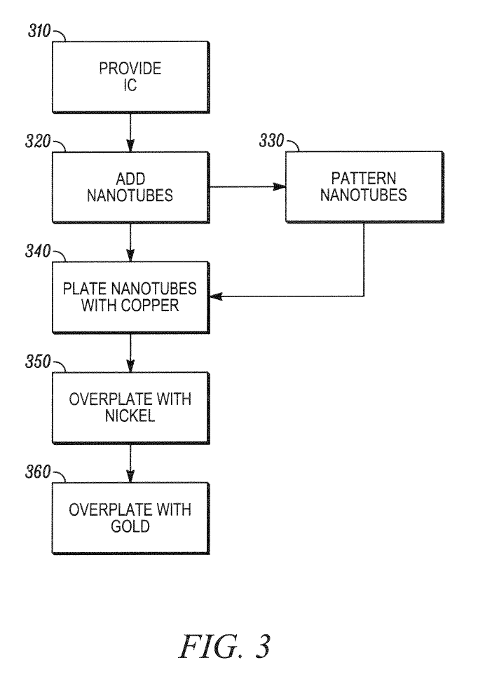

Having now described the arrangement of the various structural elements of our invention, we now describe, with reference to FIG. 3, a process for fabricating an integrated circuit having carbon nanotube interconnects. An integrated circuit has I/O pads redistributed on a top layer in a full or partial array that is at least two rows deep (310). The exposed portions of the I/O pads on the integrated circuit are covered with carbon nanotubes (320) and/or carbon nanotubes with metallic overlayers. The nanotubes provide a means for electrical and thermal interconnect of the integrated circuit to a next level substrate which can be an interposer substrate or motherboard. The carbon nanotubes are formed in traditional fashion such as vapor phase deposition from ferrocene and xylene. After the nanotubes are grown on the substrate they are overplated with electroless copper, with the carbon nanotube providing the catalyst and nucleation agent for the electroless copper (340). Because no additional catalyst is needed to initiate the electroless plating process on the carbon nanotube, the nanotube is the only surface that will plate, thus preventing shorting between the I/O pads. The plating process can be applied to nanotubes that are conductive or semiconductive, individual or clumped. After the electroless copper plating is completed, secondary layers of electroless nickel and gold may also be plated on the copper (350, 360).

In an alternate embodiment, the carbon nanotubes are deposited over the entire surface of the integrated circuit, and then patterned to remove the excess nanotubes from all locations except the I/O pads (330).

In summary, without intending to limit the scope of the invention, fabrication of an integrated circuit having carbon nanotube interconnects according to a method consistent with certain embodiments of the invention can be carried out by depositing carbon nanotubes on the I/O pads of an integrated circuit and plating the nanotubes with metal. This enables very dense flip chip and wafer scale packaging of high I/O count integrated circuits that require interconnects with good second level electrical and thermal conductivity. The copper and/or copper-nickel-gold plated overlayers significantly increase the electrical conductivity of the carbon nanotubes without degrading their thermal conductivity. In addition the metallic overlayers enable traditional next level attachment techniques such as solder or conductive adhesives.

Those skilled in the art will recognize that the present invention has been described in terms of exemplary embodiments based upon use of a silicon integrated circuit chip. However, the invention should not be so limited, since other variations will occur to those skilled in the art upon consideration of the teachings herein, and many alternatives, modifications, permutations and variations may become apparent in light of the foregoing description. Accordingly, it is intended that the present invention embrace all such alternatives, modifications and variations as fall within the scope of the appended claims.

What is claimed is:

1. An integrated circuit having carbon nanotube interconnects, comprising:
an integrated circuit chip having a plurality of input/output pads disposed on an upper layer thereof, said pads arranged in an array having at least two rows; and
carbon nanotubes disposed on the plurality of input/output pads sufficient to provide electrical and thermal interconnection of the integrated circuit chip to another circuit.

2. The integrated circuit having carbon nanotube interconnects as described in claim 1, wherein the carbon nanotubes are plated with electroless copper.

3. The integrated circuit having carbon nanotube interconnects as described in claim 2, wherein the copper plated nanotubes are further plated with an additional layer of nickel.

4. The integrated circuit having carbon nanotube interconnects as described in claim 3, wherein the copper plated nanotubes are further plated with an additional layer of gold.

5. An integrated circuit having carbon nanotube interconnects, comprising:
an integrated circuit chip having a plurality of input/output pads disposed on an upper layer thereof, said pads arranged in an array having at least two rows;
carbon nanotubes disposed on the plurality of input/output pads; and
one or more metal layers plated on the carbon nanotubes sufficient to provide electrical and thermal interconnection of the integrated circuit chip to another circuit.

6. The integrated circuit having carbon nanotube interconnects as described in claim 5, wherein the one or more metal layers is selected from the group consisting of copper, nickel, gold, platinum, tin lead, and alloys thereof.

7. A method of forming an integrated circuit having carbon nanotube interconnects, comprising:
providing an integrated circuit chip having a plurality of input/output pads disposed on an exposed layer thereof;
disposing carbon nanotubes over at least a portion of the exposed layer, so as to cover at least a portion of the plurality of input/output pads; and
providing an overlayer of copper on at least a portion of the carbon nanotubes from a solution of electroless copper such that the carbon nanotube acts as a catalyst and nucleation agent for the copper.

8. The method as described in claim 7, further comprising, after disposing the carbon nanotubes, patterning said disposed carbon nanotubes sufficient to remove carbon nanotubes from all portions of the exposed layer except the plurality of input/output pads.

9. The method as described in claim 7, further comprising, after providing an overlayer of copper, providing a layer of nickel on the copper.

10. The method as described in claim 9, further comprising, after providing an overlayer of nickel, providing a layer of gold on the nickel.
